(19) United States
(12) Patent Application Publication
(10) Pub. No.: US 2017/0057154 A1
(43) Pub. Date: Mar. 2, 2017

(54) IMPRINT APPARATUS, IMPRINT METHOD, AND METHOD OF PRODUCING ARTICLE

(71) Applicant: CANON KABUSHIKI KAISHA, Tokyo (JP)

(72) Inventors: Tatsuya Hayashi, Utsunomiya-shi (JP); Hisanobu Azuma, Utsunomiya-shi (JP); Keiji Emoto, Saitama-shi (JP); Yoshikazu Miyajima, Utsunomiya-shi (JP)

(21) Appl. No.: 15/245,070

(22) Filed: Aug. 23, 2016

(30) Foreign Application Priority Data
Aug. 31, 2015 (JP) 2015-171200

(51) Int. Cl. B29C 59/02; B05D 1/00; B05C 11/10; H01L 21/027; B05C 9/02

(52) U.S. Cl. CPC B29C 59/022; H01L 21/0271; B05C 9/02; B05C 11/10; B05D 1/005; B29C 2059/023; B29L 2031/34

(57) ABSTRACT

An imprint apparatus according to an embodiment of the present invention includes a supply unit configured to supply an imprint material on a substrate, a pattern formation unit including a holder holding a mold, the pattern formation unit being configured to bring the mold in contact with the imprint material supplied by the supply unit to form a pattern, a prevention unit configured to supply a gas in a direction intersecting a direction along the substrate to prevent a foreign matter from attaching to the substrate, and a removal unit configured to locally supply a fluid to the substrate to remove a foreign matter on the substrate.

### BACKGROUND OF THE INVENTION

Field of the Invention

The present invention relates to an imprint apparatus, an imprint method, and a method of producing an article.

Description of the Related Art

An imprint method is known as a method of forming a fine pattern on a substrate to produce a semiconductor device, for example. The imprint method includes shaping an imprint material by using a mold having a convex-concave pattern so as to form a transferred pattern of the convex-concave pattern on a substrate.

If a foreign matter is attached to the substrate before the formation of the pattern, the foreign matter is entrapped in the convex-concave pattern of the mold when the mold is pressed against the imprint material. This may result in a failure of formation of a desired transferred pattern, decreasing a yield of final products.

A stage disclosed in Japanese Patent Laid-Open No. 2013-251462 includes a gas outlet in an upper surface of the stage. A gas from the gas outlet is forced to constantly flow in a direction along the substrate so as to prevent a foreign matter from attaching to the substrate.

### SUMMARY OF THE INVENTION

An embodiment of the present invention provides an imprint apparatus and an imprint method in which defective pattern formation caused by a foreign matter attached to a substrate is reduced.

An imprint apparatus according to an embodiment of the present invention includes: a supply unit configured to supply an imprint material on a substrate; a pattern formation unit including a holder holding a mold, the pattern formation unit being configured to bring the mold in contact with the imprint material supplied by the supply unit to form a pattern; a prevention unit configured to supply a gas in a direction intersecting a direction along the substrate to prevent a foreign matter from attaching to the substrate; and a removal unit configured to locally supply a fluid to the substrate to remove a foreign matter on the substrate.

Further features of the present invention will become apparent from the following description of exemplary embodiments with reference to the attached drawings.

### BRIEF DESCRIPTION OF THE DRAWINGS

FIG. 1 is a view illustrating a configuration of an imprint apparatus according to a first embodiment.

FIGS. 2A to 2C are views illustrating a configuration of a foreign matter removal device according to the first embodiment.

FIG. 3 is a flowchart of pattern formation according to the first embodiment.

FIG. 4 is a view illustrating a partition disposed for the foreign matter removal device according to the first embodiment.

FIG. 5 is a view illustrating a configuration of a foreign matter removal device according to a second embodiment.

FIGS. 6A and 6B are views illustrating a configuration of a foreign matter removal device according to a third embodiment.

### DESCRIPTION OF THE EMBODIMENTS

### First Embodiment

### Configuration of Apparatus

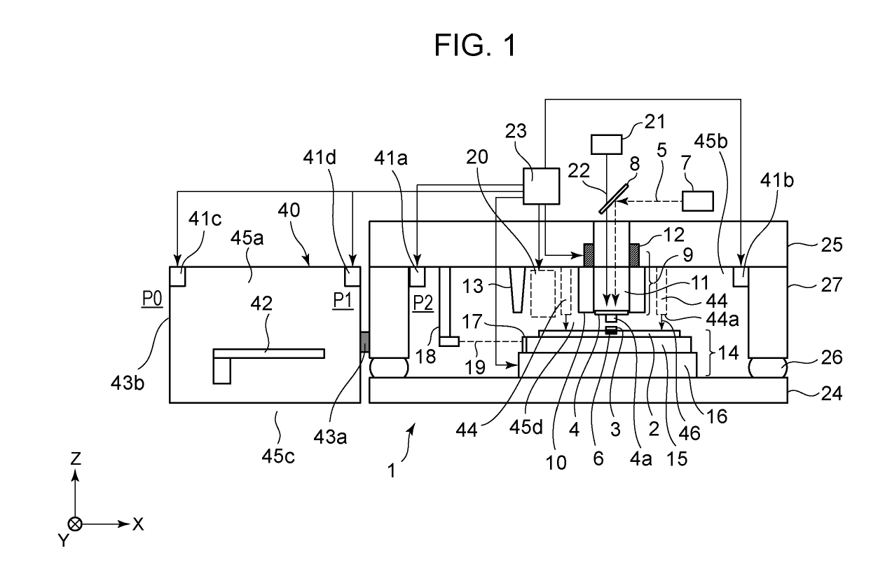

A first embodiment of the present invention is described. FIG. 1 is a view illustrating a configuration of an imprint apparatus according to the first embodiment. A Z-axis extends parallel to an irradiation axis of an ultraviolet light 5 incident on a substrate 2 (a vertical axis), and an X-axis and a Y-axis extend perpendicular to each other in a plane perpendicular to the Z-axis.

In an imprint apparatus 1, an imprint material 3 on the substrate 2 is brought into contact with a mold 4 so as to provide the imprint material 3 with an energy required for curing, and thus a convex-concave pattern of the mold 4 is transferred to the imprint material 3. As a result, the imprint apparatus 1 forms a cured material including a pattern.

The imprint material 3 is formed of a curable composition (may be referred to as an uncured resin), which cures when an energy required for curing is applied thereto. Examples of the energy for curing include an electromagnetic wave and heat. Examples of the electromagnetic wave include an infrared light, visible light, and ultraviolet light in a wavelength range of 10 nm or more to 1 mm or less.

The curable composition cures when irradiated with a light or heated. A photocurable composition, which cures when irradiated with a light, at least includes a polymerizable composition and a photopolymerization initiator. The photocurable composition may further include a non-polymerizable composition or a solvent as needed. The non-polymerizable composition may be at least one selected from a group consisting of a sensitizer, hydrogen donor, internal mold release agent, surfactant, antioxidant, and polymer component.

A spin coater or a slit coater is used to deposit the imprint material 3 in film form on the substrate 2. Alternatively, a liquid injection head may be used to deposit the imprint material 3 in droplets, in island film form constituted by connected droplets, or in film form. The imprint material 3 may have a viscosity (viscosity at 25° C.) of 1 mPa·s or more and 100 mPa·s or less, for example.

The substrate 2 may be formed of glass, ceramic, metal, semiconductor, or resin, for example. A member formed of a material different from that of the substrate 2 may be formed on the surface of the substrate 2 as needed. Specific examples of the substrate 2 include a silicon wafer, compound semiconductor wafer, and quartz glass.

Hereinafter, an example in which the imprint material 3 curable by application of the ultraviolet light 5 is used is described.

The mold 4 has a rectangular outer peripheral shape. The mold 4 has a pattern portion 4a including a three-dimensional convex-concave pattern such as a circuit pattern on the surface facing the substrate 2. The mold 4 is formed of a material through which the ultraviolet light 5 can pass. In this embodiment, the mold 4 is formed of quartz.

The imprint apparatus 1 presses the pattern portion 4a against one pattern region 6 one time. In other words, one pattern region 6 has a size corresponding to the size of the pattern to be transferred by pressing the pattern portion 4a against the imprint material 3 (bringing the pattern portion 4a into contact with the imprint material 3) one time.

An irradiation unit 7 is configured to output the ultraviolet light 5 toward a mirror 8 in a step of curing the imprint material 3. The ultraviolet light 5 reflected by the mirror 8 is applied to the pattern region 6 through the mold 4. The irradiation unit 7 includes a light source (not illustrated) and an optical element (not illustrated) configured to adjust an intensity and intensity distribution, for example, of the ultraviolet light 5 for properly curing the imprint material 3.

A mold stage (pattern formation unit) 9 includes a holder 10 holding the mold 4 and a drive unit 11 configured to move the mold 4 while holding the holder 10. The holder 10 attracts a light incidence surface of the mold 4 to which the ultraviolet light 5 is applied (surface opposite to the pattern portion 4a) with a vacuum suction force or electrostatic force. For example, when the holder 10 holds the mold 4 with the vacuum suction force, the holder 10 is connected to a vacuum pump (not illustrated) installed outside the imprint apparatus 1. The mold 4 is attached or detached by switching ON/OFF state of a negative pressure generated by the vacuum pump.

The holder 10 and the drive unit 11 each have an opening 12 at the center through which the ultraviolet light 5 travels toward the substrate 2. The drive unit 11 moves the mold 4 in the Z-axis direction to selectively perform the pressing (imprint) of the mold 4 against the imprint material 3 or the releasing (mold releasing) of the mold 4 from the imprint material 3. Examples of an actuator employed in the drive unit 11 include a linear motor and an air cylinder.

The drive unit 11 may include a plurality of drive systems, such as a coarse motion drive system and a fine motion drive system, so as to position the mold 4 with high accuracy. The drive unit 11 may further include another drive unit configured to move the mold 4, not only in the Z-axis direction, but also in the X-axis direction and the Y-axis direction, or to rotate the mold 4 in a rotational direction about the X, Y, and Z-axes. The pressing of the mold 4 against the imprint material 3 and the releasing of the mold 4 from the imprint material 3 may be performed either by moving the mold 4 in the Z-axis direction or by moving the substrate 2 in the Z-axis direction by a drive unit 16, which is described later. Alternatively, the pressing or the releasing may be performed by moving both the mold 4 and the substrate 2 relative to each other.

A supply unit 13 is configured to supply an uncured imprint material 3 onto the substrate 2. The supply unit 13 is positioned away from a mold stage 9 in the X-axis direction. The position or the total supply amount of the imprint material 3 in droplets state is determined by the thickness of the pattern to be formed on the substrate 2 or the density of the convex-concave pattern of the pattern portion 4a.

A substrate stage 14 includes a substrate holding unit 15 holding the substrate 2 and the drive unit 16 configured to move the substrate 2 held by the substrate holding unit 15 in an X-Y plane. The substrate holding unit 15 holds the substrate 2 with a vacuum suction force or electrostatic force.

The drive unit 16 is configured to move the substrate 2 in the X, Y, and Z-axes directions. Examples of an actuator employed in the drive unit 16 include a linear motor and a planar pulse motor. The drive unit 16 may include a drive unit configured to move the substrate 2 in the X-axis direction and the Y-axis direction and to rotate the substrate 2 in a rotational direction about the X, Y, and Z-axes. With this configuration, the position of the substrate 2 is able to be controlled in six directions.

A mirror 17 is disposed on the substrate stage 14. An interferometer 18 applies a laser light 19 to the mirror 17 to determine the position of the substrate stage 14 in the six directions (X, Y, Z, oX, oY, and oZ). In FIG. 1, only the mirror 17 for determining the position in the X-axis direction is illustrated, and mirrors for determining the position in the Y-axis direction and the Z-axis direction are not illustrated.

A control unit 23, which is described later, sends instructions based on the measurement result of the interferometer 18 to the substrate stage 14 in order to position the substrate 2. The control unit 23 positions the substrate 2 at a position directly below the supply unit 13 (hereinafter, may be referred to as a supply position) or at a position facing the mold 4 (a pattern formation position, which is, hereinafter, may be referred to as an imprint position), for example.

A removal device (removal unit) 20 is configured to remove a foreign matter 29 attached to the substrate 2. The removal device 20 is configured to blow (supply) a gas (fluid) to a local area of the substrate 2 at a higher flow velocity than a flow velocity of a gas blown by an air curtain unit 44, which is described later. The removal device 20 is described in detail later.

A measurement unit 21 is configured to detect a mark on each of the mold 4 and the substrate 2 to determine the shape and the size of the pattern region 6. In addition, the measurement unit 21 determines a positional relationship between the pattern portion 4a and the pattern region 6 in the X-Y plane. The measurement unit 21 emits a light 22 toward the mirror 8. The light 22 passes through the mirror 8 and reaches the mark (not illustrated) on each of the pattern portion 4a and the substrate 2.

The control unit 23 is constituted by a computer including a CPU, ROM, and RAM, for example. The control unit 23 is connected to the irradiation unit 7, the drive unit 11, the supply unit 13, the substrate stage 14, the interferometer 18, the removal device 20, and the measurement unit 21 through lines. In addition, the control unit 23 is connected to adjusters 41a, 41b, 41c, and 41d, the air curtain unit (prevention unit) 44, a mold carrier unit (not illustrated), and a substrate carrier unit (not illustrated) through lines. The adjusters 41a to 41d, the mold carrier unit, and the substrate carrier unit are described later.

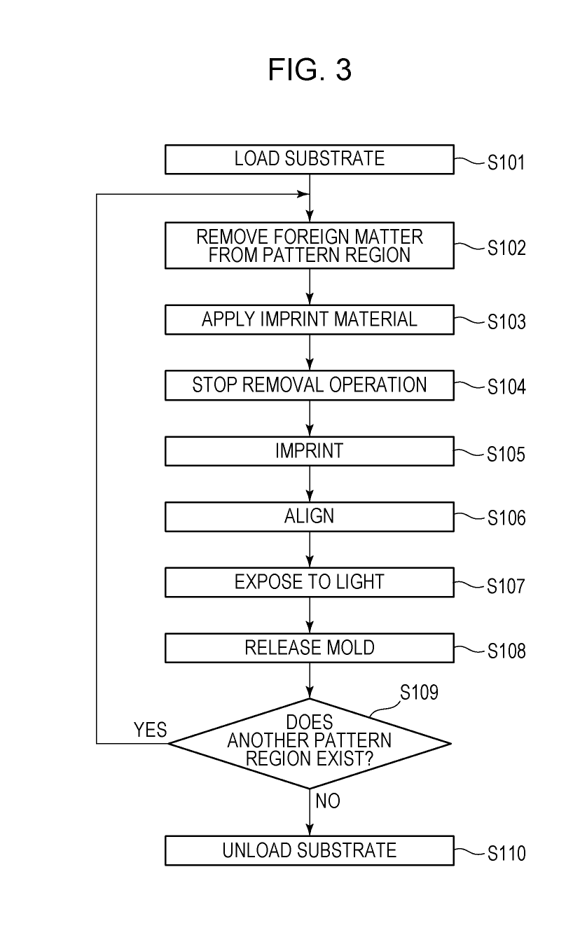

The control unit 23 controls the action of each component based on the program, which is indicated in the flowchart in FIG. 3, in the ROM of the control unit 23. The control unit 23 collectively controls the pattern formation operation on the pattern region 6 (imprint process) and the removal operation of a foreign matter by the removal device 20.

The control unit 23 may be disposed in a common housing of the imprint apparatus 1 or may be disposed in a housing separate from the common housing as long as the above-described functions of the control unit 23 remain.

The imprint apparatus 1 includes a base surface plate 24 on which the substrate stage 14 is disposed, a bridge surface plate 25 supporting the mold stage 9, and a support 27 extending from the base surface plate 24 in a vertical direction and supporting the bridge surface plate 25 with a vibration damper 26 between the support 27 and the base surface plate 24. The vibration damper 26 damps vibrations to be transferred from the floor to the bridge surface plate 25.

In addition, the imprint apparatus 1 includes the mold carrier unit (not illustrated) configured to carry the mold 4 from the outside of the imprint apparatus 1 to the holder 10 and the substrate carrier unit configured to carry the substrate 2 from the outside of the imprint apparatus 1 to the substrate holding unit 15.

In a carrier portion 40, a carrier unit 42 and adjusters (adjustment units) 41c and 41d configured to adjust a pressure P1 in a space 45a in the carrier portion 40 are disposed. A load lock 43a separates the carrier portion 40 from a space 45b in which the supply position and the removal device 20 are located (the space in which the substrate 2 is disposed). The carrier portion 40 includes a wall 43b separating the space 45a in the carrier portion 40 from the external space.

The adjuster 41c includes a blower unit configured to send a gas into the space 45a. The adjuster 41d includes a discharging unit configured to discharge the gas from the space 45a. The adjusters 41c and 41d adjust the amount of the gas in the space 45a to constantly maintain the space 45a at a predetermined pressure.

The air curtain unit 44 surrounds the mold holder 10. In the space 45b, the air curtain unit 44 supplies the gas in the vertical direction (direction intersecting a planar direction along the substrate) through its supply outlet facing the substrate 2. The gas forms a layered curtain-like gas flow 46. The gas flow 46 prevents a foreign matter from attaching to the substrate 2 during the imprint operation.

The adjuster 41a includes a blower unit configured to send a gas into the space 45b. The adjuster 41b includes a discharging unit configured to discharge the gas from the space 45b. The adjusters 41a and 41b adjust the amount of the gas in the space 45b to constantly maintain the space 45b at a predetermined pressure.

The control unit 23 controls the pressures by using the adjusters 41a, 41b, 41c, and 41d to satisfy P0<P2< P1 in which P0 is a gas pressure outside the imprint apparatus 1 and the carrier portion 40, P1 is a pressure in the space 45a, and P2 is a pressure in the space 45b. A difference between the pressure P0 and the pressure P2 and a difference between the pressure P1 and the pressure P2 are each a few pascal (Pa). With this configuration, a foreign matter 29 in a space 45c, which is a space outside the imprint apparatus 1 and the carrier portion 40, is unlikely to enter the spaces 45a and 45b.

The air curtain unit 44 constantly generates a gas flow 46. This forms a space 45d enclosed by the gas flow 46 and the substrate 2. This configuration prevents the foreign matter 29 generated in the space 45b from entering the space 45d. Thus, this configuration prevents the foreign matter 29 from attaching to the pattern region 6 supplied with the imprint material 3. Herein, the term “prevent” also implies that “reduce the attachment of the foreign matter 29 compared to a case without the air curtain unit 44”.

A target region of the removal device 20 for removing a foreign matter is at least a portion of the pattern region 6 not supplied with the imprint material 3 by the supply unit 13. The removal device 20 is located between the supply unit 13 and a side of the air curtain unit 44 adjacent to the supply unit 13.

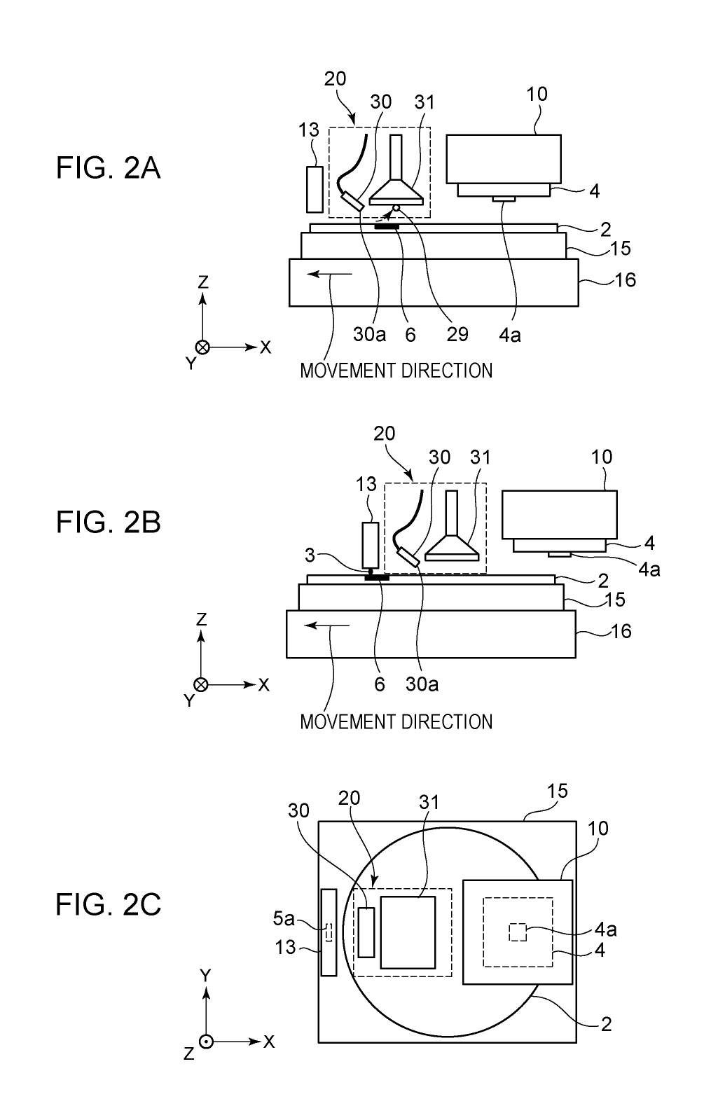

FIGS. 2A, 2B, and 2C are views illustrating a configuration of the removal device 20 according to the first embodiment. FIG. 2A illustrates a state in which the removal device 20 is removing the foreign matter 29 on the pattern region 6. FIG. 2B illustrates a state in which the supply unit 13 is supplying the imprint material 3 to the pattern region 6 from which the foreign matter 29 has been removed.

The removal device 20 includes a gas supply portion 30 and a gas collection portion 31. The gas supply portion 30 blows a gas through a gas supply outlet 30a toward the pattern region 6 facing the gas supply outlet 30a while the substrate stage 14 is being moved to move the pattern region 6 toward the supply position of the imprint material 3. A physical force generated by the contact of the gas detaches the foreign matter 29, which is attached to the substrate 2, from the surface of the pattern region, and the foreign matter 29 floats in the air. The gas collection portion 30 is connected to a vacuum pump (not illustrated), for example, and is configured to collect the gas by using a negative pressure. The gas collection portion 31 collects the floating foreign matter 29 together with the gas blown by the gas supply portion 30.

The flow velocity of the gas supplied by the removal device 20 is higher than that of the gas supplied by the air curtain unit 44. The removal of the attached foreign matter 29 requires a larger force than the supply of the gas by the air curtain unit 44.

Examples of the gas blown by the gas supply portion 30 include an inert gas or the like such as clean dry air, nitrogen, and carbon dioxide, for example. Alternatively, a mixture including an inert gas and carbon dioxide in a particulate solid form (dry ice) may be used as the gas. The use of the mixture provides higher removal effect compared to the case in which only a gas is used to force the foreign matter 29 to float in the air, since the particles come in physical contact with the foreign matter 29 attached to the substrate 2.

After the pattern region 6 passes through the position directly below the removal device 20 (hereinafter, may be referred to as a removal position), the imprint material 3 is supplied to the pattern region 6 from which the foreign matter 29 has been removed.

FIG. 2C is a view of the removal device 20 viewed from the +Z direction. As illustrated in FIG. 2C, the gas supply outlet 30a of the removal device 20 is located between the supply unit 13 and the holder 10. This configuration enables the pattern region 6, which is a target of the removal operation, to be subjected to a removal operation of the foreign matter 29, while being moved to the supply position. This reduces a decrease in throughput compared to the removal device 20 located at a different position.

The phase “the gas supply outlet 30a of the removal device 20 is located between the supply unit 13 and the holder 10” means that the following positional relationship is satisfied when the substrate stage 14 is viewed from the +Z direction (upper side in the vertical direction). At least a portion of the gas supply outlet 30a of the removal device 20 is located on a straight line extending between the center of an outlet port 5a of the supply unit 13 through which the imprint material 3 is discharged and the center of the pattern region 4a of the mold 4 held by the holder 10.

The flow velocity and the flow angle of the gas from the gas supply portion 30 are suitably adjusted. The gas supply outlet 30a can be located such that gas molecules come in contact with the pattern region 6 obliquely from the above, for example. The gas supply outlet 30a can be located so as to supply a gas obliquely toward the pattern region 6 positioned farthest from the destination of the substrate stage 14, which moves from the holder 10 to the supply unit 13. In other words, as illustrated in FIGS. 2A and 2B, the gas supply outlet 30a can be located to supply a gas in a direction having a +X direction component.

Since the removal device 20 is a separate component from the substrate stage 14, a relative speed between the removal device 20 and the substrate stage 14 at the time of contact between the gas and the foreign matter 29 on the pattern region 6 is able to be increased. This enables the gas to come in contact with the substrate 2 with a greater force. Thus, the removal of the foreign matter is effectively removed.

### Imprint Method

Next, an imprint method according to the present embodiment is described with reference to a flowchart illustrated in FIG. 3. The control unit 23 runs programs indicated in the flowchart while controlling the above-described control targets. As a result, a cured imprint material 3 having a pattern is formed on each of a plurality of pattern regions 6 on the substrate 2.

The mold 4 is held in the holder 10 before the steps in the flowchart. The substrate carrier unit carries the substrate 2 into the imprint apparatus 1 such that the substrate 2 is held on the substrate holding unit 15 (S101). Then, the substrate stage 14 moves the substrate 2 in the −X direction (FIG. 2A) such that the pattern region 6, which is a first area to be processed, passes through the removal position.

The removal device 20 removes the foreign matter 29 from the pattern region 6 while the pattern region (target region) 6 not supplied with the imprint material 3 is being moved to the supply position of the imprint material 3. Specifically, while the pattern region 6 not supplied with the imprint material 3 is passing under the gas supply outlet 30a, the removal device 20 blows a gas to the pattern region 6 and collects the blown gas (S102). The control unit 23 causes the removal device 20 to perform the removal operation regardless of whether the foreign matter 29 is attached to the pattern region 6 or not.

Then, a supply step (S103) is performed in which the supply unit 13 supplies an imprint material (resist) on the pattern region 6 positioned at the supply position. The control unit 23 stops the removal operation of the foreign matter 29, which is performed by the removal device 20, (S104) until the pattern region 6, which has been subjected to the removal operation by the removal device 20 at the step S102 and supplied with the pattern imprint material 3 at the step S103, passes under the removal device 20 again. The control unit 23 controls the removal device 20 so as not to perform the removal operation on the region supplied with the imprint material 3.

Then, the control unit 23 drives the drive unit 16 to move the pattern region 6 on the substrate 2 to the imprint position. Subsequently, the control unit 23 drives the drive unit 11 to press the mold 4 against the imprint material 3 on the substrate 2. As a result of the pressing, the imprint material 3 fills the concave-convex portion of the pattern portion 4a (S105).

Then, the control unit 23 determines a relative position of the mark on the pattern portion 4a and the mark on the pattern region 6 by using the measurement unit 21. Based on the measurement result, an amount of relative positional displacement between the pattern portion 4a and the pattern region 6 is calculated. The control unit 23 controls the substrate stage 14 based on the calculated amount of positional displacement to align the pattern portion 4a with the pattern region 6 (S106).

Then, the irradiation unit 7 irradiates the pattern region 6 with the ultraviolet light 5 to cure the imprint material 3 (S107). In a mold releasing step, the control unit 23 drives the drive unit 11 to separate the mold 4 from the substrate 2 (S108). As a result, the surface of the pattern region 6 on the substrate 2 has the cured imprint material 3 having a transferred pattern of the pattern portion 4a.

The control unit 23 determines whether another pattern region 6 on which a pattern needs to be formed exists (S109). When the control unit 23 determines that another pattern region 6 does not exist (NO), the substrate carrier unit carries out the substrate 2. When the control unit 23 determines that another pattern region 6 exists (YES), the substrate stage 14 is moved in the −X direction again for removing the foreign matter 29 from the other pattern region 6 and supplying the imprint material 3 on the pattern region 6. The process returns to S102 to remove the foreign matter 29 attached to another pattern region 6. The repetition of the steps S102 to S108 forms a plurality of patterns on one substrate 2.

As described above, the air curtain unit 44 and the pressure adjusters 41a to 41d for adjusting the pressure are in operation almost all the time. Thus, the flow velocity of the gas generated by the air curtain unit 44 is made lower than that of the gas supplied by the removal device 20. With this configuration, when the substrate stage 14 moves such that the pattern region 6 passes under a gas supply outlet 44a, the gas from the air curtain unit 44 does not vaporize the imprint material 3 on the substrate 2, does not change the positions of the droplets of the imprint material 3, and does not change any other characteristics.

In contrast, the removal device 20 operates only when the pattern region 6 not supplied with the imprint material 3 passes under the removal device 20. Thus, the removal device 20 may generate a high-pressure gas flowing at a high flow velocity compared to the air curtain unit 44. The removal device 20 blows a gas with a great force through the gas supply outlet 30a, which is positioned to face the substrate 2, to a local area of the substrate 2 such that the gas comes in contact with the foreign matter 29. This reliably removes the foreign matter 29 strongly attached to the substrate 2.

As described above, since the imprint apparatus 1 includes the adjusters 41a, 41b, 41c, and 41d, the foreign matter 29 is prevented from entering the spaces 45b and 45d in which the supply unit 13, the removal device 20, and the mold stage 9 of the imprint apparatus 1 are disposed. In addition, the air curtain unit 44 prevents the foreign matter 29 in the space 45b from entering the space 45d. If the foreign matter 29 is attached to the substrate 2 moving in the space 45b or the space 45d by the substrate stage 14, the foreign matter 29 is able to be removed by the removal device 20.

The combination of the adjusters 41a, 41b, 41c, and 41d for the above-described pressure adjustment, the air curtain unit 44, and the removal device 20 prevents the foreign matter 29 from being sandwiched between the mold 4 and the substrate 2 in the imprint step. This reduces the defective pattern formation and reduces a decrease in a yield of devices, for example. In addition, this reduces a damage to the pattern portion 4a caused by the sandwiched foreign matter 29. This may eliminate the need for replacing the mold 4, which is expensive, reducing the cost required in the device production.

Since the removal device 20 blows the gas toward the substrate 2 from the position facing the substrate 2 such that the gas comes in contact with the substrate 2, the removal device 20 also removes a powder of the imprint material 3 scattered on the substrate 2 and attached to the substrate 2 during the mold releasing.

The removal device 20 only needs to perform the removal operation of the foreign matter 29 at least on a next region to which the imprint material 3 is to be supplied (a portion of a region not supplied with the imprint material) of the pattern region 6 not supplied with the imprint material 3. That is, the removal device 20 only needs to remove the foreign matter 29 from a local area, not the entire area of the substrate 2, and thus a large-scale removal device is not required. The removal device 20 does not require a large mounting space compared to one configured to perform the removal operation of the foreign matter 29 on the entire area of the substrate 2.

In addition, the removal device 20 only needs to perform the removal operation of the foreign matter 29 only for a short time until the start of the supply of the imprint material 3 to the pattern region 6, which is to be subjected to the removal operation of the foreign matter 29. In other words, the removal device 20 stops the removal operation after the step S103 of supplying the imprint material 3 starts and until the step S108 ends, i.e., during the pattern formation operation.

This prevents the imprint material 3 from vaporizing by the gas blown by the removal device 20, preventing a defective pattern formed by using the mold 4. In addition, this reduces the power consumed by the removal device 20. In this embodiment, when the removal operation stops, the removal device 20 does not blow the gas through the gas supply outlet 30a toward the pattern region 6 to be subjected to the removal operation of the foreign matter 29. Alternatively, when the removal operation stops, the removal device 20 blows the gas through the gas supply outlet 30a in a sufficiently small amount so as not to have an effect on the imprint material 3 disposed on the substrate 2.

If the removal device 20 blows the gas after the imprint material 3 is supplied, the flow velocity is controlled to be lower than the flow velocity at the step S102.

In this embodiment, the removal device 20 is located between the holder 10 and the supply unit 13, but the position of the removal device 20 is not limited to this position. The removal device 20 may be located on an opposite side of the supply unit 13 from the holder 10. In addition, the direction of the gas blown by the gas supply portion 30 is not limited to the X-axis direction. The gas supply portion 30 may blow a gas in the Y-axis direction and the gas collection portion 31 may be located to receive the gas. This configuration prevents the gas including the foreign matter 29 from applying to the pattern portion 4a or the supply unit 13 if the gas collection portion 31 fails to collect the gas.

In addition, when the removal device 20 is located as described in the first embodiment, the gas blown from the gas supply outlet 30a may flow to a side of the supply unit 13. The gas may dry the imprint material 3 attached to the outlet port 5a of the supply unit 13. In such a case, the dried imprint material 3 becomes particles and disperses in the imprint apparatus 1, leading to an increase in the amount of the foreign matter 29 in the imprint apparatus 1.

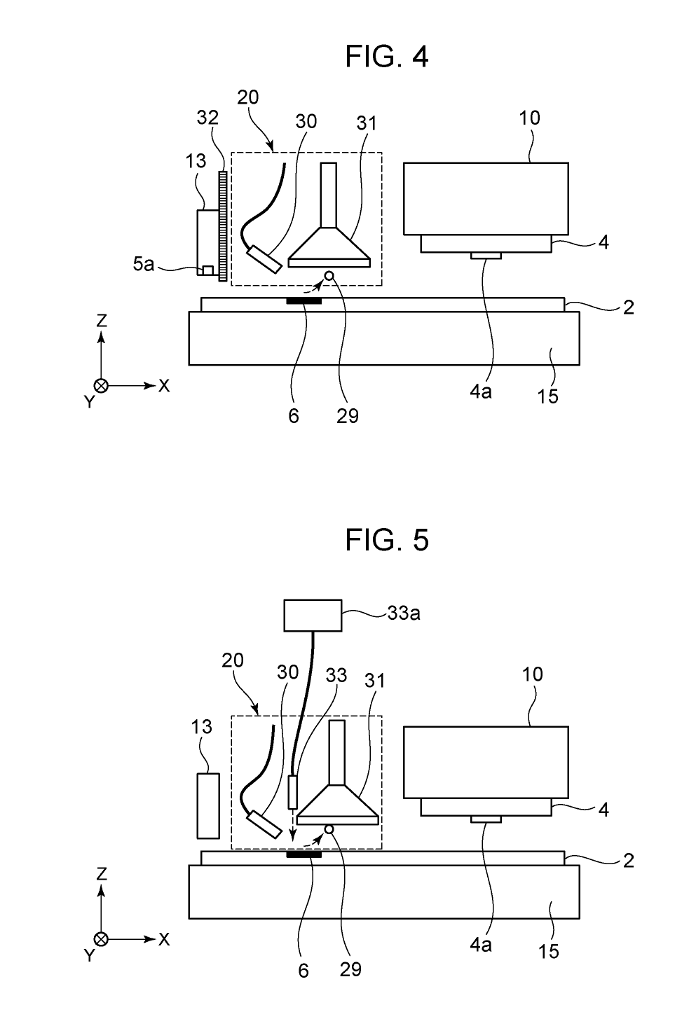

To solve the problem, a partition 32 can be disposed between the removal device 20 and the supply unit 13 as illustrated in FIG. 4. The partition 32 changes the direction of the gas flowing toward the supply unit 13 to the Y-axis direction. The partition 32 extending in the Y-axis direction suppresses the gas blown from the gas supply outlet 30a from flowing toward the supply unit 13 and prevents the imprint material 3 attached to the outlet port 5a from drying. This reduces an increase in the amount of the foreign matter 29 caused by the gas supply portion 30.

The gas blown by the gas supply portion 30 may lower the temperature of the pattern region 6. In such a case, a heating unit (irradiation unit 33, which is described later, for example) may be disposed to heat the pattern region 6 and properly adjust the temperature of the pattern region 6.

### Second Embodiment

Next, an imprint apparatus 1 according to a second embodiment is described with reference to FIG. 5. A removal device 20 according to this embodiment further includes an irradiation unit 33 configured to apply a laser light to the substrate 2 in addition to the components of the removal device 20 described in the first embodiment. The irradiation unit 33 as a heating unit irradiates the foreign matter 29 and the substrate 2 with a laser light when the gas supply portion 30 removes the foreign matter 29 attached to the substrate 2. The surface of each of the foreign matter 29 and the substrate 2 is thermally expanded when heated instantaneously with the laser light. The force generated at this time weakens the adhesion between the foreign matter 29 and the substrate 2.

The irradiation operation with the laser light emitted by the irradiation unit 33, which is performed in addition to the blowing operation of the gas to the pattern region 6 on the substrate 2 from the gas supply portion 30, enables the foreign matter 29 attached to the pattern region 6 to be readily removed.

In the imprint step, the foreign matter 29 is prevented from being sandwiched between the mold 4 and the substrate 2, reducing the defective pattern formation. This reduces a decrease in the yield of devices, for example. In addition, this reduces a damage to the pattern portion 4a caused by the sandwiched foreign matter 29. This eliminates the need for replacing the mold 4, which is expensive, reducing the cost required in the device production.

Since the removal device 20 ejects the liquid particles from the position facing the substrate 2 toward the substrate 2 such that the liquid particles come in contact with the substrate 2, the imprint material 3 in powdered form, which is dispersed and attached to the substrate 2 during the mold releasing, is also removed.

The laser light emitted from the irradiation unit 33 can be in a visible wavelength range so as to be easily absorbed by the foreign matter 29 and the substrate 2 and so as not to cure the imprint material 3. In addition, the irradiation unit 33 can include a laser light source 33a, which is a pulsed laser light source configured to emit an instantaneous intense pulsed light, in order to heat the foreign matter 29 and the substrate 2 instantaneously.

The heating unit may be a device configured to directly apply thermal energy by using a Peltier device or a heater, for example, instead of the irradiation unit 33, which is a device configured to apply heat through optical energy.

### Third Embodiment

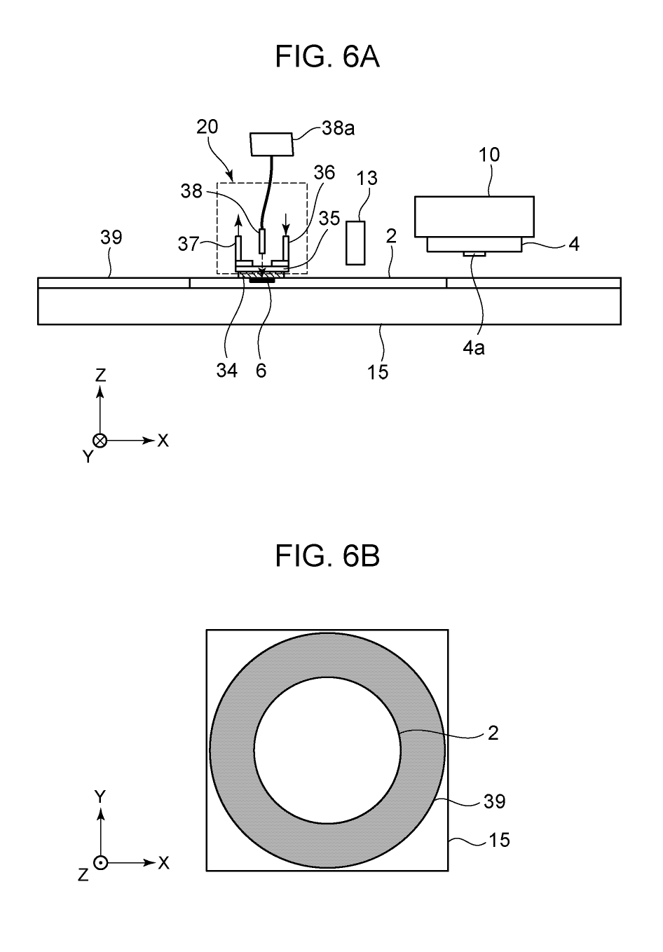

An imprint apparatus 1 according to a third embodiment of the present invention is described with reference to FIGS. 6A and 6B. A removal device 20 in the third embodiment is located at a position away from the supply unit 13 in the −X direction, or on an opposite side of the supply unit 13 from the holder 10.

The removal device 20 includes a liquid film formation portion ((first) supply outlet) 35 configured to form a liquid film 34 between the liquid film formation portion 35 and the substrate 2, a liquid supply portion 36 configured to supply a liquid (fluid) to the liquid film formation portion 35, a liquid collection portion 37 configured to collect the liquid of the liquid film 34, and an irradiation unit 38. The liquid film formation portion 35 has an opening through which the liquid passes and includes a planar portion for preventing the liquid film 34 from moving away from a portion of the substrate 2 around the opening. The liquid film formation portion 35 functions as a supporting unit for supporting the liquid film 34. The liquid supplied by the liquid supply portion 36 is a pure water, for example. The liquid constituting the liquid film 34 is always maintained as a clean liquid by the liquid supply portion 36 and the liquid collection portion 37.

As illustrated in FIG. 6B, the imprint apparatus 1 includes an auxiliary portion 39 surrounding the substrate 2 and having a surface at the same level as the surface of the substrate 2 on which the pattern is to be formed. When the drive unit 16 moves the substrate 2 away from the position under the liquid film formation portion 35, the liquid film 34 is held between the liquid film formation portion 35 and the auxiliary portion 39.

The liquid film 34 sliding on the substrate 2 removes the foreign matter 29 attached to the substrate 2. The foreign matter 29 is collected by the liquid collection portion 37.

When the substrate 2 is moved, the liquid film 34 is elongated a little in the movement direction of the substrate 2, but the liquid film 34 is not divided. The liquid film formation portion 35 is disposed such that the liquid film 34 has a thickness (dimension of the liquid film 34 in the Z-axis direction) of 1 mm or less, preferably 0.1 mm or less in view of the length of the elongated portion. This prevents the elongated portion of the liquid film 34 from becoming too long.

In addition, the removal device 20 has the irradiation unit 38 as a heating unit. The central portion of the liquid film formation portion 35 is formed of quartz so as to allow a laser light emitted from the irradiation unit 38 to be applied to the substrate 2.

The laser light emitted from the irradiation unit 38 can be in a visible wavelength range so as to be easily absorbed by the foreign matter 29 and the substrate 2 and so as not to cure the imprint material 3. In addition, a laser light source 38a can be a pulsed laser light source configured to emit an instantaneous intense pulsed light in order to heat the foreign matter 29 and the substrate 2 instantaneously.

The laser light emitted from the irradiation unit 38 is absorbed by the substrate 2, the foreign matter 29, and the liquid film 34. A portion of the liquid film 34 which is irradiated with the laser light is boiled instantaneously, and micro bubbles are generated in the liquid film 34. The force generated due to the generation of the micro bubbles and a buoyance of the bubbles force the foreign matter 29 attached to the pattern region 6 on the substrate 2 to float from the surface of the substrate 2. The floating foreign matter 29 is carried along the flow of the liquid film 34, which is generated by the liquid supply portion 36 and the liquid collection portion 37, and is collected by the liquid collection portion 37. The foreign matter 29 is removed in this way.

A method of forming a pattern by using the removal device 20 according to this embodiment is substantially the same as that in the first embodiment. This embodiment differs from the other embodiments in that the pattern region 6 supplied with the imprint material 3 moves to the position under the removal device 20 through the supply position, since the removal device 20 is located on the opposite side of the supply unit 13 from the holder 10. This configuration prevents the pattern region 6 supplied with the imprint material 3 from coming in contact with the liquid film 34, and thus the imprint material 3 and the liquid film 34 are not mixed together and positions of the liquid droplets of the imprint material 3 are not changed, for example.

In this embodiment, in the step S104 of “stopping the removal operation of the foreign matter 29”, the circulation of the liquid by using the liquid supply portion 36 and the liquid collection portion 37 is stopped based on the instruction by the control unit 23.

This configuration prevents the foreign matter 29 from being sandwiched between the mold 4 and the substrate 2 in the imprint step and reduces the defective pattern formation. Thus, a decrease in the yield of devices, for example, is reduced. In addition, a damage to the pattern portion 4a caused by the sandwiched foreign matter 29 is reduced. This eliminates the need for replacing the mold 4, which is expensive, reducing the cost required in the device production.

Since the removal device 20 ejects the liquid particles from the position facing the substrate 2 toward the substrate 2 such that the liquid particles come in contact with the substrate 2, the imprint material 3 in powdered form, which is dispersed and attached to the substrate 2 during the mold releasing, is also removed.

In this embodiment, the liquid supply portion 36 supplies the pure water, but the liquid is not limited to the pure water. A cleaning liquid for cleaning the substrate may be used, for example. In addition, the irradiation unit 38 is an optional component. If the irradiation unit 38 is not used, the foreign matter 29 is removed by the power to circulate the liquid.

### Other Embodiments

In the above-described first to third embodiments, the imprint apparatus 1 performs the removal operation regardless of whether the foreign matter 29 exists or not. However, the imprint apparatus 1, for example, may include a detection unit configured to detect the foreign matter 29, and the imprint apparatus 1 may perform the removal operation only when the foreign matter 29 is detected by the detection unit.

The removal operation of the foreign matter 29 is not necessarily performed after the end of each pattern formation on the pattern region 6. The removal operation of the foreign matter 29 may be collectively performed on multiple pattern regions 6 having no pattern after the end of pattern formation on multiple pattern regions 6. In particular, if the moving speed of the substrate stage 14 is lowered or the movement distance of the substrate stage 14 is increased by the removal operation of the removal device 20, the frequency of the removal operation is reduced to achieve both of prevention of a decrease in the throughput and the removal of the foreign matter 29.

Herein, the “foreign matter” is a substance that is unnecessary to the pattern formation. Examples of the foreign matter include a solid material of the imprint material 3 ejected from the supply unit 13 and dried after floated in the mist form, fine particles of a component of the imprint apparatus 1, and a dust entered the imprint apparatus 1 from the outside.

Herein, the “removal operation” is an operation to move at least one particle of the foreign matter 29 attached to the substrate 2 away from the substrate 2 and remove the particle of the foreign matter 29.

The imprint apparatus 1 according to the above-described first to third embodiments may employ a thermal curing method instead of a photo-curing method. The imprint material 3 may be an imprint material curable by various electromagnetic radiation including a light or an imprint material curable by heat. The imprint material is selected in accordance with the curing method employed by the imprint apparatus.

### Method of Producing Article

The cured material including a pattern formed by using the imprint apparatus 1 is used as a permanent portion of at least one of various articles or is used as a portion temporarily used for producing various articles. Examples of the article include an electrical circuit element, optical element, MEMS, recording element, sensor, and mold, for example. Examples of the electrical circuit element include a volatile or non-volatile semiconductor memory such as a DRAM, SRAM, flush memory, and HRAM and a semiconductor element such as an LSI, CCD, image sensor, and FPGA, for example. Examples of the mold include a mold for imprint, for example.

The cured material including a pattern is used as it is as a component of at least a portion of the above-described article, or is used temporarily as a resist mask. The resist mask is removed after an etching process or an ion implantation process is performed in the step of processing the substrate. The processing step may include any other well-known processing steps such as development, oxidation, film formation, vapor deposition, planarization, dicing, bonding, and packaging.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-171200, filed Aug. 31, 2015, which is hereby incorporated by reference herein in its entirety.

What is claimed is:

1. An imprint apparatus comprising:
a supply unit configured to supply an imprint material on a substrate;
a pattern formation unit including a holder holding a mold, the pattern formation unit being configured to bring the mold in contact with the imprint material supplied by the supply unit to form a pattern;
a prevention unit configured to supply a gas in a direction intersecting a direction along the substrate to prevent a foreign matter from attaching to the substrate; and
a removal unit configured to locally supply a fluid to the substrate to remove a foreign matter on the substrate.

2. The imprint apparatus according to claim 1, wherein the removal unit supplies the fluid at a flow velocity higher than that of the gas supplied by the prevention unit.

3. The imprint apparatus according to claim 1, wherein the removal unit supplies the fluid to a region of the substrate having no imprint material.

4. The imprint apparatus according to claim 1, further comprising a stage configured to move while holding the substrate, wherein
the removal unit controls the supply of the fluid in accordance with a position of the stage.

5. The imprint apparatus according to claim 1, wherein, after the imprint material is supplied to a region of the substrate on which the removal unit has performed a removal operation of a foreign matter, the removal unit does not perform the removal operation of the foreign matter on the region supplied with the imprint material.

6. The imprint apparatus according to claim 1, wherein, after the imprint material is supplied to a region of the substrate on which the removal unit has performed a removal operation of a foreign matter, the removal unit supplies the fluid to the region supplied with the imprint material at a lower flow velocity than when the removal unit supplies the fluid to a region not supplied with the imprint material.

7. The imprint apparatus according to claim 1, wherein one removal operation of the removal unit removes the foreign matter from at least a portion of a region of the substrate not supplied with the imprint material.

8. The imprint apparatus according to claim 1, wherein the removal unit has a fluid supply outlet through which the fluid is supplied to the substrate, the fluid supply outlet facing the substrate.

9. The imprint apparatus according to claim 8, wherein the fluid is a gas, and the removal unit includes a gas collection portion configured to collect the gas which was supplied to the substrate through the fluid supply outlet.

10. The imprint apparatus according to claim 8, wherein the fluid supply outlet is located between the supply unit and the holder.

11. The imprint apparatus according to claim 10, further comprising a stage configured to move to a supply position of the imprint material and move to a formation position of the pattern, wherein
the fluid supply outlet is positioned so as to supply the gas obliquely toward a region of the substrate on which the imprint material is not supplied, the region being located farthest from a destination of the stage with the fluid supply outlet therebetween.

12. The imprint apparatus according to claim 9, further comprising a partition between the fluid supply outlet and the supply unit, the partition being configured to change a flow direction of the gas traveling from the removal unit toward the supply unit.

13. The imprint apparatus according to claim 1, wherein the removal unit includes a heating unit configured to heat a region of the substrate to which the gas is supplied.

14. The imprint apparatus according to claim 1, wherein the prevention unit has a supply outlet of the gas at a position facing the substrate, the supply outlet being located between a fluid supply outlet of the removal unit and a formation position of the pattern.

15. An imprint method comprising:
performing a removal operation of a foreign matter by supplying a fluid to a target region of a substrate in accordance with movement of a stage on which the substrate is disposed;
supplying an imprint material to the target region;
moving the target region to an imprint position while the removal operation on the target region supplied with the imprint material is stopped; and
pressing a mold against the imprint material on the target region to form a pattern.

16. A method of producing an article comprising:
forming a pattern on a substrate by using an imprint apparatus; and
processing the substrate on which the pattern is formed in the forming step, wherein
the imprint apparatus includes:
a supply unit configured to supply an imprint material on the substrate;
a pattern formation unit including a holder holding a mold, the pattern formation unit being configured to bring the mold in contact with the imprint material supplied by the supply unit to form a pattern;
a prevention unit configured to supply a gas in a direction intersecting a direction along the substrate to prevent a foreign matter from attaching to the substrate; and
a removal unit configured to locally supply a fluid to the substrate to remove a foreign matter attached to the substrate.
